(19) United States
(12) Patent Application Publication
(10) Pub. No.: US 2024/0425974 A1
(43) Pub. Date: Dec. 26, 2024

(54) DEPOSITION OF RUTHENIUM-CONTAINING FILMS BY NON-AROMATIZABLE CYCLIC-DIENE RUTHENIUM(0) COMPLEXES

(71) Applicant: L'Air Liquide, Société Anonyme pour I'Exploitation des Procédès Georges Claude, Paris (FR)

(72) Inventors: Jacky Chun Ho YIM, Tokyo (JP); Yuki ITO, Yokosuka (JP); Teruo BEPPU, Yokosuka (JP); Raphael ROCHAT, Yokohama (JP)

(21) Appl. No.: 18/209,952

(22) Filed: Jun. 14, 2023

(51) Int. Cl. C23C 16/18; C23C 16/448; C23C 16/455

(52) U.S. Cl. CPC C23C 16/18; C23C 16/448; C23C 16/45553

(57) ABSTRACT

Disclosed are chemicals suitable for use as a volatile precursor for vapor phase depositions of Ru containing materials, the chemical represented by the formula (NACD)-Ru-Lₓ, where x=1-3 and NACD is a non-aromatizable cyclic diene.

### TECHNICAL FIELD

The field of the invention is volatile, metalorganic chemical suitable for use as precursors for vapor phase depositions of metal containing materials on surfaces, such as surface films and coating.

### BACKGROUND OF THE INVENTION

Ruthenium is a very promising candidate in thin films technology, particularly for microelectronics and optoelectronics applications, for several reasons: high work function, better thermal stability, low bulk resistivity, low specific electrical resistivity, chemical inactivity with wide range of metals, and good adhesion properties.

Specifically, ruthenium and ruthenium-containing thin films are considered for diffusion barrier, electrodes, capacitors, interconnect, memory, and so on. In addition, Ruthenium films have shown promise as hard mask material for patterning. For these applications, an area-selective deposition (ASD) method would allow for a more overall efficient assembly process for microstructures.

Chemical vapor deposition (CVD) and more preferably atomic layer deposition (ALD) are premiere techniques to achieve the target thin films. In general, desired properties for Ru CVD and ALD precursors include liquid state at room temperature and thermal stability during vaporization, which facilitates delivery of precursor and ease of storage and handling. High volatility and appropriate process windows are also important parameters. To be compatible for back end of line (BEOL) applications, <400° C. is required. However, if the process window is too low, this may lead to an uncontrolled process and is detrimental to ASD.

### Selected Prior Art Ru Precursors

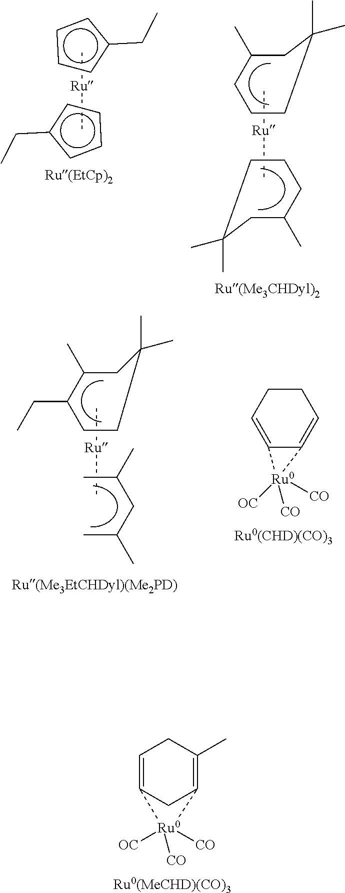

EtCp is ethylcyclopentadienyl, Me₃CHDyl is 2,6,6-trimethylcyclohexadienyl,
Me₃EtCHDyl is 2-ethyl-2,6,6-trimethylcyclohexadienyl, Me₂PD is 2,4-pentadienyl,
CHD is cyclohexadiene, MeCHD is methylcyclohexadiene.

A large variety of Ru(II) CVD (Chemical vapor deposition) precursors are known and well-studied. For example, Ru^{II}(EtCp)₂ is one of the best known Ru precursors. Other examples include gem-dimethyl substituted cyclohexadienyl ruthenium complexes such in U.S. Pat. No. 8,557,339 B2 (Ru^{II}(Me₃CHDyl)₂) and U.S. Pat. No. 10,131,987 B2 (Ru^{II}(Me₃CHDyl)(Me₂PD)). However, Ru(II) suffers from relatively low volatility and typically results in significant amounts of carbon and oxygen impurities in the deposited films. For example, Ru^{II}(EtCp)₂ has a vapor pressure of 0.1 torr at 73° C. In addition, Ru^{II} generally requires the use of O₂ as a coreactant. The use of O₂ is incompatible with certain substrate materials. Furthermore, Ru^{II} typically results in only ruthenium oxide films and not pure Ru films.

Ru⁰ complexes are already in the preferred oxidation state for pure Ru films. Ru⁰ complexes also do not require the use of O₂ as a coreactant, thereby expanding the range of substrate materials.

Tricarbonyl(1,3-cyclohexadiene) ruthenium (Ru⁰(CHD)(CO)₃) is a well known Ru⁰ precursor to deposit both ruthenium films. For example, Lazarz et al. has described the use of Ru⁰(CHD)(CO)₃ for CVD of metallic Ru films at as low temperatures as 150° C. However, Ru⁰(CHD)(CO)₃ suffers from limited thermal stability. For example, JP2002212112A demonstrates that tricarbonyl(1,3-cyclohexadiene) ruthenium decomposes at 169.6° C. To properly deliver the precursor, the precursor needs to be vaporized without decomposition. The stability of a liquid precursor is essential for a reproducible process, as well as for ease of storage, handling and transport. In addition, if a precursor is insufficiently volatile, then increased heat is needed, where again thermal stability is required.

Furthermore, it was noted by Hoover et al. that tricarbonyl(1,3-cyclohexadiene) ruthenium is not a viable candidate for ALD of Ru as a Ru film can be deposited with this precursor without a coreactant at substrate temperatures between 15° and 350° C. Because the temperature for pyrolysis is very low, self-limiting reactions are contaminated by concurrent parasitic CVD, making ALD infeasible. Improvement of thermal stability would allow for ALD applications using Ru⁰ precursors, which as mentioned above have enhanced volatility when compared to Ru^{II} counterparts.

The low pyrolysis temperature also suggests this precursor has limited application in ASD. Low pyrolysis temperature typically signifies significant gas-phase reaction contributions, which promotes depositions on all surfaces and hinders selectivity. Increasing the process window where pyrolysis does not occur, would enhance the likelihood of successfully identifying workable selective deposition conditions.

Prior art analysis of the deposition of (Ru⁰(CHD)(CO)₃) has identified the byproducts to be CO and benzene. The benzene is formed from the cyclohexadiene ligand. Cyclohexadiene is easily dehydrogenated to benzene, which is thermodynamically favorable due to aromatic stabilization. Ruthenium is also well known as a dehydrogenation catalyst. These factors contribute as large driving forces toward the decomposition of Ru⁰(CHD)(CO)₃.

U.S. Pat. No. 8,357,614B2 describes the use of substituted-1,4-cyclohexadiene tricarbonyl ruthenium, including Ru⁰(MeCHD)(CO)₃, to deposit pure ruthenium films between 250-350° C. using H₂ as a coreactant. Notably, Ru films were obtained from temperature above 250° C. without the use of a coreactant, which is an increase of 100° C. for the minimum pyrolysis temperature of Ru⁰(CHD)(CO)₃. In addition, Ru⁰(MeCHD)(CO)₃ was shown to be thermally stable up to −190° C. by TGA at 1060 torr, which suggests higher thermal stability than the Ru⁰(CHD)(CO)₃ predecessor. Alkyl-substituted cyclohexadiene ruthenium carbonyl complexes such as Ru⁰(MeCHD)(CO)₃ have been recently shown to be effective precursors for area-dependent deposition of ruthenium thin films.

However, Ru⁰(MeCHD)(CO)₃ is a mixture of isomers in the liquid phase. These isomers may have different vapor boiling points, evaporation behaviors and thermal stabilities, due at least partially to their stereochemical geometries. Over time or during the deposition process, one isomer could be enriched, which poses a risk for drift in any vapor processes.

### SUMMARY OF INVENTION

The invention may be understood in relation to the following numbered embodiments:

SENTENCE 1. A chemical suitable for use as a volatile precursor for vapor phase depositions of Ru containing materials, the chemical represented by the formula (NACD)-Ru-Lₓ, wherein x=1-3 and NACD is a non-aromatizable cyclic diene.

SENTENCE 2. The chemical of SENTENCE 1, wherein the NACD has the formula I:

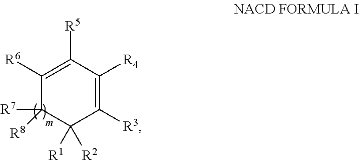

wherein R¹ and R² is a substituent covalently bound to a ring structure carbon via a carbon or silicon atom, and R¹ and R² may be the same or different,
wherein R³, R⁴, R⁵, R⁶, R⁷ and R⁸ each is independently selected from H or a covalently bound substituent,
wherein L is a neutral ligand, and
wherein m=0-3.

SENTENCE 3. The chemical of SENTENCE 2, wherein R1 and R² are selected from C₁-C₆ linear alkyl, C₁-C₆ branched alkyl, C₁-C₆ cyclic alkyl, C₁-C₆ alkenyl, C₁-C₆ alkynyl, C₁-C₆ alkylphenyl, C₁-C₆ alkenylphenyl, C₁-C₆ alkynylphenyl, aryl, C₁-C₆ fluoroalkyl or —SiR^{x}R^{y}R^{z}; and wherein for —SiR^{x}R^{y}R^{z}, R^{x}, R^{y}, and R^{z} each is independently selected from H, C₁-C₆ linear alkyl, C₁-C₆ branched alkyl, C₁-C₆ cyclic alkyl, C₁-C₆ alkenyl, C₁-C₆ alkylphenyl, C₁-C₆ alkenylphenyl, aryl, F, Cl, Br, and I.

SENTENCE 4. The chemical of SENTENCE 2 or 3, wherein R³, R⁴, R⁵, R⁶, R⁷ and R⁸ each is independently selected from H, C₁-C₆ linear alkyl, C₁-C₆ branched alkyl, C₁-C₆ cyclic alkyl, C₁-C₆ alkenyl, C₁-C₆ alkylphenyl, C₁-C₆ alkenylphenyl, aryl, vinyl, or —SiR^{x}R^{y}R^{z}; wherein R^{x}, R^{y}, and R^{z} each is independently selected from H, C₁-C₆ linear alkyl, C₁-C₆ branched alkyl, C₁-C₆ cyclic alkyl, C₁-C₆ alkenyl, C₁-C₆ alkylphenyl, C₁-C₆ alkenylphenyl, aryl, F, Cl, Br, and I.

SENTENCE 5. The chemical of SENTENCE 2, 3 or 4, wherein m=1.

SENTENCE 6. The chemical of SENTENCE 2, 3, 4, or 5, wherein R¹ and R² are C₁-C₄ linear alkyl or branched alkyl substituents, and R³-R⁸ are independently H, C₁-C₄ linear alkyl or branched alkyl substituents.

SENTENCE 7. The chemical of SENTENCE 2, 3, 4, 5 or 6, wherein R¹ and R² are both methyl groups.

SENTENCE 8. The chemical of SENTENCE 2, 3, 4, 5, 6, or 7 wherein L is selected from CO, NCR⁹, CNR⁹, PR⁹₃; where R⁹ is independently selected from H, C₁-C₆ linear alkyl, C₁-C₆ branched alkyl, C₁-C₆ cyclic alkyl, C₁-C₆ alkenyl, C₁-C₆ alkylphenyl, C₁-C₆ alkenylphenyl, aryl, vinyl, or —SiR^{x}R^{y}R^{z}; wherein R^{x}, R^{y}, and R^{z} each is independently selected from H, C₁-C₆ linear alkyl, C₁-C₆ branched alkyl, C₁-C₆ cyclic alkyl, C₁-C₆ alkenyl, C₁-C₆ alkylphenyl, C₁-C₆ alkenylphenyl, aryl, F, Cl, Br, I; and combinations thereof, when x>1.

SENTENCE 9. The chemical of SENTENCE 2, 3, 4, 5, 6, 7 or 8, wherein x=3 and L is CO.

SENTENCE 10. The chemical of SENTENCE 2, selected from:
Ru(6,6-dimethyl-1,3-cyclohexadiene)(CO)₃, Ru(6,6-diethyl-1,3-cyclohexadiene)(CO)₃, Ru(6,6-di(n-propyl)-1,3-cyclohexadiene)(CO)₃, Ru(6,6-di(isopropyl)-1,3-cyclohexadiene)(CO)₃,
Ru(6-ethyl-6-methyl-1,3-cyclohexadiene)(CO)₃, Ru(6-methyl-6-(n-propyl)-1,3-cyclohexadiene)(CO)₃, Ru(6-methyl-6-(iso-propyl)-1,3-cyclohexadiene)(CO)₃,
Ru(6-(n-butyl)-6-methyl-1,3-cyclohexadiene)(CO)₃, Ru(6-(sec-butyl)-6-methyl-1,3-cyclohexadiene)(CO)₃,
Ru(2,6,6-trimethyl-1,3-cyclohexadiene)(CO)₃, Ru(1,5,5-trimethyl-1,3-cyclohexadiene)(CO)₃, Ru(3,6,6-trimethyl-1,3-cyclohexadiene)(CO)₃, Ru(2,6,6-triethyl-1,3-cyclohexadiene)(CO)₃, Ru(1,5,5-triethyl-1,3-cyclohexadiene)(CO)₃, Ru(3,6,6-triethyl-1,3-cyclohexadiene)(CO)₃,
Ru(2,6,6-tri-iso-propyl-1,3-cyclohexadiene)(CO)₃, Ru(1,5,5-tri-iso-propyl-1,3-cyclohexadiene)(CO)₃, Ru(2,6,6-n-iso-propyl-1,3-cyclohexadiene)(CO)₃, Ru(1,5,5-n-iso-propyl-1,3-cyclohexadiene)(CO)₃,
Ru(2-ethyl-6,6-dimethyl-1,3-cyclohexadiene)(CO)₃, Ru(1-ethyl-5,5-dimethyl-1,3-cyclohexadiene)(CO)₃, Ru(6-ethyl-2,6-dimethyl-1,3-cyclohexadiene)(CO)₃,
Ru(2,6-diethyl-6-methyl-1,3-cyclohexadiene)(CO)₃, Ru(6,6-diethyl-2-methyl-1,3-cyclohexadiene)(CO)₃,
Ru(1,5-diethyl-5-methyl-1,3-cyclohexadiene)(CO)₃, Ru(5,5-diethyl-1-methyl-1,3-cyclohexadiene)(CO)₃,
Ru(3-ethyl-6,6-dimethyl-1,3-cyclohexadiene)(CO)₃, Ru(2-ethyl-5,5-dimethyl-1,3-cyclohexadiene)(CO)₃, Ru(6-ethyl-3,6-dimethyl-1,3-cyclohexadiene)(CO)₃,
Ru(3,6-diethyl-6-methyl-1,3-cyclohexadiene)(CO)₃, Ru(6,6-diethyl-3-methyl-1,3-cyclohexadiene)(CO)₃,
Ru(2,5-diethyl-5-methyl-1,3-cyclohexadiene)(CO)₃, Ru(5,5-diethyl-2-methyl-1,3-cyclohexadiene)(CO)₃,
Ru(6,6-dimethyl-2-iso-propyl-1,3-cyclohexadiene)(CO)₃, Ru(5,5-dimethyl-1-iso-propyl-1,3-cyclohexadiene)(CO)₃, Ru(2,6-dimethyl-6-iso-propyl-1,3-cyclohexadiene)(CO)₃, Ru(6-methyl-2,6-di-iso-propyl-1,3-cyclohexadiene)(CO)₃, Ru(2-methyl-6,6-di-iso-propyl-1,3-cyclohexadiene)(CO)₃,
Ru(5-methyl-1,5-di-iso-propyl-1,3-cyclohexadiene)(CO)₃, Ru(1-methyl-5,5-di-iso-propyl-1,3-cyclohexadiene)(CO)₃,
Ru(6,6-dimethyl-3-iso-propyl-1,3-cyclohexadiene)(CO)₃, Ru(5,5-dimethyl-2-iso-propyl-1,3-cyclohexadiene)(CO)₃, Ru(3,6-dimethyl-6-iso-propyl-1,3-cyclohexadiene)(CO)₃, Ru(6-methyl-3,6-di-iso-propyl-1,3-cyclohexadiene)(CO)₃, Ru(3-methyl-6,6-di-iso-propyl-1,3-cyclohexadiene)(CO)₃,
Ru(5-methyl-2,5-di-iso-propyl-1,3-cyclohexadiene)(CO)₃, Ru(2-methyl-5,5-di-iso-propyl-1,3-cyclohexadiene)(CO)₃,
Ru(6,6-dimethyl-2-n-propyl-1,3-cyclohexadiene)(CO)₃, Ru(5,5-dimethyl-1-n-propyl-1,3-cyclohexadiene)(CO)₃, Ru(2,6-dimethyl-6-n-propyl-1,3-cyclohexadiene)(CO)₃, Ru(6-methyl-2,6-di-n-propyl-1,3-cyclohexadiene)(CO)₃, Ru(2-methyl-6,6-di-n-propyl-1,3-cyclohexadiene)(CO)₃,
Ru(5-methyl-1,5-di-n-propyl-1,3-cyclohexadiene)(CO)₃,
Ru(1-methyl-5,5-di-n-propyl-1,3-cyclohexadiene)(CO)₃,
Ru(6,6-dimethyl-3-n-propyl-1,3-cyclohexadiene)(CO)₃, Ru(5,5-dimethyl-2-n-propyl-1,3-cyclohexadiene)(CO)₃, Ru(3,6-dimethyl-6-n-propyl-1,3-cyclohexadiene)(CO)₃, Ru(6-methyl-3,6-di-n-propyl-1,3-cyclohexadiene)(CO)₃, Ru(3-methyl-6,6-di-n-propyl-1,3-cyclohexadiene)(CO)₃,
Ru(5-methyl-2,5-di-n-propyl-1,3-cyclohexadiene)(CO)₃, Ru(2-methyl-5,5-di-n-propyl-1,3-cyclohexadiene)(CO)₃,
Ru(1,3,5,5-tetramethyl-1,3-cyclohexadiene)(CO)₃,
Ru(1,3,5,5-tetraethyl-1,3-cyclohexadiene)(CO)₃,
Ru(2,3,5,5-tetramethyl-1,3-cyclohexadiene)(CO)₃,
Ru(3,4,6,6-tetramethyl-1,3-cyclohexadiene)(CO)₃,
Ru(2,3,5,5-tetraethyl-1,3-cyclohexadiene)(CO)₃,
Ru(3,4,6,6-tetraethyl-1,3-cyclohexadiene)(CO)₃,
Ru(1-ethyl-3,5,5-trimethyl-1,3-cyclohexadiene)(CO)₃,
Ru(2-ethyl-4,6,6-trimethyl-1,3-cyclohexadiene)(CO)₃,
Ru(3-ethyl-1,5,5-trimethyl-1,3-cyclohexadiene)(CO)₃,
Ru(4-ethyl-2,6,6-trimethyl-1,3-cyclohexadiene)(CO)₃,
Ru(5-ethyl-1,3,5-trimethyl-1,3-cyclohexadiene)(CO)₃,
Ru(6-ethyl-2,4,6-trimethyl-1,3-cyclohexadiene)(CO)₃,
Ru(1,3-diethyl-5,5-dimethyl-1,3-cyclohexadiene)(CO)₃,
Ru(2,4-diethyl-6,6-dimethyl-1,3-cyclohexadiene)(CO)₃,
Ru(1,5-diethyl-3,5-dimethyl-1,3-cyclohexadiene)(CO)₃,
Ru(2,6-diethyl-4,6-dimethyl-1,3-cyclohexadiene)(CO)₃,
Ru(3,5-diethyl-1,5-dimethyl-1,3-cyclohexadiene)(CO)₃,
Ru(4,6-diethyl-2,6-dimethyl-1,3-cyclohexadiene)(CO)₃,
Ru(1,2,3,5,5-pentamethyl-1,3-cyclohexadiene)(CO)₃,
Ru(2,3,4,6,6-pentamethyl-1,3-cyclohexadiene)(CO)₃,
Ru(1,2,3,5,5-pentaethyl-1,3-cyclohexadiene)(CO)₃,
Ru(2,3,4,6,6-pentaethyl-1,3-cyclohexadiene)(CO)₃,
Ru(1-ethyl-2,3,5,5-tetramethyl-1,3-cyclohexadiene)(CO)₃,
Ru(2-ethyl-3,4,6,6-tetramethyl-1,3-cyclohexadiene)(CO)₃,
Ru(2-ethyl-1,3,5,5-tetramethyl-1,3-cyclohexadiene)(CO)₃,
Ru(3-ethyl-2,4,6,6-tetramethyl-1,3-cyclohexadiene)(CO)₃,
Ru(3-ethyl-1,2,5,5-tetramethyl-1,3-cyclohexadiene)(CO)₃,
Ru(4-ethyl-2,3,6,6-tetramethyl-1,3-cyclohexadiene)(CO)₃,
Ru(5-ethyl-1,2,5,5-tetramethyl-1,3-cyclohexadiene)(CO)₃,
Ru(6-ethyl-2,3,4,6-tetramethyl-1,3-cyclohexadiene)(CO)₃,
Ru(gem-dimethylcyclopentadiene)(CO)₃, Ru(gem-diethylcyclopentadiene)(CO)₃,
Ru(1,3,5,5-tetramethyl-1,3-cyclohexadiene)(NCMe)₃, Ru(1,3,5,5-tetramethyl-1,3-cyclohexadiene)(CNMe)₃,
Ru(1,3,5,5-tetramethyl-1,3-cyclohexadiene)(NCEt)₃, Ru(1,3,5,5-tetramethyl-1,3-cyclohexadiene)(CNEt)₃,
Ru(1,3,5,5-tetramethyl-1,3-cyclohexadiene)(NCnBu)₃, Ru(1,3,5,5-tetramethyl-1,3-cyclohexadiene)(CNnBu)₃,
Ru(1,3,5,5-tetramethyl-1,3-cyclohexadiene)(NCsBu)₃, Ru(1,3,5,5-tetramethyl-1,3-cyclohexadiene)(CNsBu)₃,
Ru(1,3,5,5-tetramethyl-1,3-cyclohexadiene)(NCtBu)₃, Ru(1,3,5,5-tetramethyl-1,3-cyclohexadiene)(CNtBu)₃,
Ru(1,3,5,5-tetramethyl-1,3-cyclohexadiene)(P(Ph)₃)₃,
Ru(1,3,5,5-tetramethyl-1,3-cyclohexadiene)(P(Me)₃)₃,
Ru(1,3,5,5-tetramethyl-1,3-cyclohexadiene)(P(Et)₃)₃,
Ru(1,3,5,5-tetramethyl-1,3-cyclohexadiene)(P(OMe)₃)₃,
Ru(1,3,5,5-tetramethyl-1,3-cyclohexadiene)(P(OCH₂)₃CMe)₃, and
combinations thereof.

SENTENCE 11. A composition comprising the chemical of SENTENCE 1, 2, 3, 4, 5, 6, 7, 8, 9 or 10.

SENTENCE 12. The composition of SENTENCE 11, wherein the composition is a vapor phase composition.

SENTENCE 13. The composition of SENTENCE 12, wherein the vapor phase composition comprises a vapor of the chemical mixed with a carrier gas.

SENTENCE 14. The composition of SENTENCE 13, wherein the carrier gas comprises Argon, Helium and/or Nitrogen gas.

SENTENCE 15. The chemical of SENTENCE 1, wherein the NACD has the formula II:

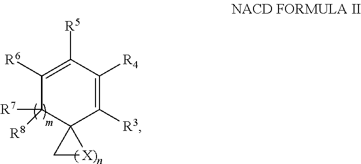

wherein R¹ and R² is a substituent covalently bound to a ring structure carbon via a carbon or silicon atom, and R¹ and R² may be the same or different,
wherein R³, R⁴, R⁵, R⁶, R⁷ and R⁸ each is independently selected from H or a covalently bound substituent,
wherein L is a neutral ligand,
wherein X is selected from —CR^{x}R^{y}—, —NR^{x}—, —O—, —S—, —SiR^{x}R^{y}—; wherein R^{x}, R^{y}, and R^{z} each is independently selected from H, C₁-C₆ linear alkyl, C₁-C₆ branched alkyl, C₁-C₆ cyclic alkyl, C₁-C₆ alkenyl, C₁-C₆ alkylphenyl, C₁-C₆ alkenylphenyl, aryl, F, Cl, Br, and I, and
wherein m=0-3 and n=1-7.

SENTENCE 16. A method of vapor phase depositing a Ru containing material on a surface, the method comprising
a) providing a substrate having a surface, and
b) exposing the substrate to a vapor phase of the chemical of SENTENCE 1, 2, 3, 4, 5, 6, 7, 8, 9, 10 or 1, under conditions suitable to form a deposited material, comprising the Ru, on the surface.

SENTENCE 17. The method of SENTENCE 16 further comprising a step of exposing the substrate to a co-reactant selected from the group consisting of H₂, NH₃, SiH₄, Si₂H₆, Si₃H₈, hydrogen containing fluids, hydrogen radicals, and mixtures thereof.

SENTENCE 18. The method of SENTENCE 16 further comprising a step of exposing the substrate to a co-reactant selected from the group consisting of O₂, O₃, H₂O, H₂O₂, oxygen containing radicals, and mixtures thereof.

SENTENCE 19. The method of SENTENCE 16, 17 or 18, wherein the deposited material is a contiguous and conformal film or layer on the surface of the substrate.

SENTENCE 20. The method of SENTENCE 19, wherein the deposited material comprises 50% to 99.99% Ru by atomic percent.

### DISCLOSURE OF INVENTION

Ruthenium precursors should ideally be liquid at 20-25 degrees C. and highly volatile such that 1 torr vapor pressure may be achieved with low heating such as 150 degrees C. or less. The precursors should be thermally stable throughout the vaporization process to reach the surface of the target deposition substrate intact. Thermal degradation products will contaminate and interfere with metallic Ruthenium deposition, as well as cause the nonproductive loss of Ru metal. Thermal stability is especially important for ALD processes to ensure that the temperature window for ALD does not overlap with a thermal CVD window (parasitic CVD). While Ru⁰(MeCHD)(CO)₃ improved over Ru⁰(CHD)(CO)₃ to meet these criteria, some deposition processes, ALD and ASD in particular, would benefit from a Ru⁰ precursor with even greater thermal stability.

We thus undertook an examination of the deposition reactions of Ru⁰(MeCHD)(CO)₃. We discovered that the decomposition byproduct from the MeCHD ligand is toluene, another aromatic compound like benzene. The thermodynamics of MeCHD to toluene are less favorable, which fits well with the observed superior thermal stability of Ru⁰(MeCHD)(CO)₃. On the basis of this observation, we theorized that CHD derivatives, or other cyclic ligands, that could not be dehydrogenated into the corresponding aromatic structure, would produce an even more stable Ru⁰ precursor. However, the decomposition pathway for this class of compounds clearly involved an aromatic leaving group. It was uncertain whether blocking this decomposition pathway would in fact render the chemical unusable as vapor deposition precursor, in particular for ALD or ASD.

Herein we demonstrate the use of cyclic dienes that are not capable of being dehydrogenated into an aromatic. These ligands are referred to herein as a non-aromatizable cyclic diene (NACD). As shown in the experiments below, NACDs thermally stabilize the Ruthenium precursors compared to Ru⁰(MeCHD)(CO)₃. This stability does not preclude use of these molecules as metallic Ruthenium vapor deposition precursors. Indeed these compounds are significantly improved over the prior art available precursors.

Preferred embodiments are as follows:

The precursor is a (NACD)-Ru-Lₓ, where x=1-3 and NACD is a non-aromatizable cyclic diene. In general, this genus of chemicals was found to be a liquid, scalable and highly volatile with increased thermal stability.

Lₓ is generally a neutral ligand. A nonexhaustive list of generally suitable neutral ligand L includes CO, NCR⁹, CNR⁹, PR⁹₃; where R⁹ is independently selected from H, C₁-C₆ linear alkyl, C₁-C₆ branched alkyl, C₁-C₆ cyclic alkyl, C₁-C₆ alkenyl, C₁-C₆ alkylphenyl, C₁-C₆ alkenylphenyl, aryl, vinyl, or —SiR^{x}R^{y}R^{z}; wherein R^{x}, R^{y}, and R^{z} each is independently selected from H, C₁-C₆ linear alkyl, C₁-C₆ branched alkyl, C₁-C₆ cyclic alkyl, C₁-C₆ alkenyl, C₁-C₆ alkylphenyl, C₁-C₆ alkenylphenyl, aryl, F, Cl, Br, and I. CO is preferred and (CO)₃ is especially preferred for Lₓ.

NACDs fall into two main structural categories:

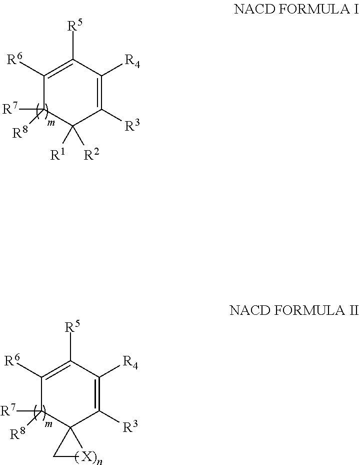

NACD formula I is a general representation of a cyclic diene having at least one gem-dialkyl or gem-disilyl substituted carbon in the ring (R¹ and R²). The NACD should have at least two unsaturated bonds as shown. Larger cyclic molecules, in which m>0, may have additional gem-substituted carbons, however only one such gem-substituted carbon will be sufficient to block the dehydrogenation pathway to an aromatic ring.

The gem-dialkyl or gem-disilyl substituted carbon's substitutions at R¹ and R² may be any carbon or silicon structure and may be the same or different. R¹ and R² may each preferably be selected from C₁-C₆ linear alkyl, C₁-C₆ branched alkyl, C₁-C₆ cyclic alkyl, C₁-C₆ alkenyl, C₁-C₆ alkynyl, C₁-C₆ alkylphenyl, C₁-C₆ alkenylphenyl, C₁-C₆ alkynylphenyl, aryl, C₁-C₆ fluoroalkyl or —SiR^{x}R^{y}R^{z}. For —SiR^{x}R^{y}R^{z}, R^{x}, R^{y}, and R^{z} each is independently selected from H, C₁-C₆ linear alkyl, C₁-C₆ branched alkyl, C₁-C₆ cyclic alkyl, C₁-C₆ alkenyl, C₁-C₆ alkylphenyl, C₁-C₆ alkenylphenyl, aryl, F, Cl, Br, and I.

In NACD formula II, n=1-7 and X may be selected from —CR^{x}R^{y}—, —NR^{x}—, —O—, —S—, —SiR^{x}R^{y}—; wherein R^{x}, R^{y}, and R^{z} each is independently selected from H, C₁-C₆ linear alkyl, C₁-C₆ branched alkyl, C₁-C₆ cyclic alkyl, C₁-C₆ alkenyl, C₁-C₆ alkylphenyl, C₁-C₆ alkenylphenyl, aryl, F, Cl, Br, and I.

In both NACD formulas I and II;
m is preferably 0-3 and more preferably 1 (such as a substituted cyclohexadiene).
R³, R⁴, R⁵, R⁶, R⁷ and R⁸ each is independently selected from H, C₁-C₆ linear alkyl, C₁-C₆ branched alkyl, C₁-C₆ cyclic alkyl, C₁-C₆ alkenyl, C₁-C₆ alkylphenyl, C₁-C₆ alkenylphenyl, aryl, vinyl, or —SiR^{x}R^{y}R^{z}; wherein R^{x}, R^{y}, and R^{z} each is independently selected from H, C₁-C₆ linear alkyl, C₁-C₆ branched alkyl, C₁-C₆ cyclic alkyl, C₁-C₆ alkenyl, C₁-C₆ alkylphenyl, C₁-C₆ alkenylphenyl, aryl, F, Cl, Br, and I.
   For m>1, additional carbon substituents are present on the additional ring carbons, each substituent also selected from the list above for R³, R⁴, R⁵, R⁶, R⁷ and R⁸.
   For m=0, R⁷ and R⁸ are not present.

One preferred subgenus of NACD formula I are substituted gem-dialkyl cyclohexadiene, where m=1, R¹ and R² are C₁-C₄ linear alkyl or branched alkyl substituents, and R³-R⁸ are independently H, C₁-C₄ linear alkyl or branched alkyl substituents. On some embodiments R¹ and R² are both C₁ i.e. methyl groups.

Another preferred subgenus of both NACD formula I and II are tris-carbonyls i.e. (CO)₃.

Yet another preferred embodiment is the subgenus of symmetric NACD formula I ligands in which a substituent on additional ring carbons to a symmetrical set of substituted ring carbons. An example is 1,3,5,5-Me₄-CHD)Ru(CO)₃. These symmetrical NACD ligands do not have isomers. Therefore, the precursor is consistently composed of the single molecule, instead of isomers, which may improve vapor deposition process stability and consistency.

Selected examples of NACDs includes:
Ru(6,6-dimethyl-1,3-cyclohexadiene)(CO)₃, Ru(6,6-diethyl-1,3-cyclohexadiene)(CO)₃, Ru(6,6-di(n-propyl)-1,3-cyclohexadiene)(CO)₃, Ru(6,6-di(isopropyl)-1,3-cyclohexadiene)(CO)₃,
Ru(6-ethyl-6-methyl-1,3-cyclohexadiene)(CO)₃, Ru(6-methyl-6-(n-propyl)-1,3-cyclohexadiene)(CO)₃, Ru(6-methyl-6-(iso-propyl)-1,3-cyclohexadiene)(CO)₃,
Ru(6-(n-butyl)-6-methyl-1,3-cyclohexadiene)(CO)₃, Ru(6-(sec-butyl)-6-methyl-1,3-cyclohexadiene)(CO)₃,
Ru(2,6,6-trimethyl-1,3-cyclohexadiene)(CO)₃, Ru(1,5,5-trimethyl-1,3-cyclohexadiene)(CO)₃, Ru(3,6,6-trimethyl-1,3-cyclohexadiene)(CO)₃, Ru(2,6,6-triethyl-1,3-cyclohexadiene)(CO)₃, Ru(1,5,5-triethyl-1,3-cyclohexadiene)(CO)₃, Ru(3,6,6-triethyl-1,3-cyclohexadiene)(CO)₃,
Ru(2,6,6-tri-iso-propyl-1,3-cyclohexadiene)(CO)₃, Ru(1,5,5-tri-iso-propyl-1,3-cyclohexadiene)(CO)₃, Ru(2,6,6-n-iso-propyl-1,3-cyclohexadiene)(CO)₃, Ru(1,5,5-n-iso-propyl-1,3-cyclohexadiene)(CO)₃,
Ru(2-ethyl-6,6-dimethyl-1,3-cyclohexadiene)(CO)₃, Ru(1-ethyl-5,5-dimethyl-1,3-cyclohexadiene)(CO)₃, Ru(6-ethyl-2,6-dimethyl-1,3-cyclohexadiene)(CO)₃, Ru(2,6-diethyl-6-methyl-1,3-cyclohexadiene)(CO)₃, Ru(6,6-diethyl-2-methyl-1,3-cyclohexadiene)(CO)₃,
Ru(1,5-diethyl-5-methyl-1,3-cyclohexadiene)(CO)₃, Ru(5,5-diethyl-1-methyl-1,3-cyclohexadiene)(CO)₃,
Ru(3-ethyl-6,6-dimethyl-1,3-cyclohexadiene)(CO)₃, Ru(2-ethyl-5,5-dimethyl-1,3-cyclohexadiene)(CO)₃, Ru(6-ethyl-3,6-dimethyl-1,3-cyclohexadiene)(CO)₃, Ru(3,6-diethyl-6-methyl-1,3-cyclohexadiene)(CO)₃, Ru(6,6-diethyl-3-methyl-1,3-cyclohexadiene)(CO)₃,
Ru(2,5-diethyl-5-methyl-1,3-cyclohexadiene)(CO)₃, Ru(5,5-diethyl-2-methyl-1,3-cyclohexadiene)(CO)₃,
Ru(6,6-dimethyl-2-iso-propyl-1,3-cyclohexadiene)(CO)₃, Ru(5,5-dimethyl-1-iso-propyl-1,3-cyclohexadiene)(CO)₃, Ru(2,6-dimethyl-6-iso-propyl-1,3-cyclohexadiene)(CO)₃, Ru(6-methyl-2,6-di-iso-propyl-1,3-cyclohexadiene)(CO)₃, Ru(2-methyl-6,6-di-iso-propyl-1,3-cyclohexadiene)(CO)₃,
Ru(5-methyl-1,5-di-iso-propyl-1,3-cyclohexadiene)(CO)₃, Ru(1-methyl-5,5-di-iso-propyl-1,3-cyclohexadiene)(CO)₃,
Ru(6,6-dimethyl-3-iso-propyl-1,3-cyclohexadiene)(CO)₃, Ru(5,5-dimethyl-2-iso-propyl-1,3-cyclohexadiene)(CO)₃, Ru(3,6-dimethyl-6-iso-propyl-1,3-cyclohexadiene)(CO)₃, Ru(6-methyl-3,6-di-iso-propyl-1,3-cyclohexadiene)(CO)₃, Ru(3-methyl-6,6-di-iso-propyl-1,3-cyclohexadiene)(CO)₃,
Ru(5-methyl-2,5-di-iso-propyl-1,3-cyclohexadiene)(CO)₃, Ru(2-methyl-5,5-di-iso-propyl-1,3-cyclohexadiene)(CO)₃,
Ru(6,6-dimethyl-2-n-propyl-1,3-cyclohexadiene)(CO)₃, Ru(5,5-dimethyl-1-n-propyl-1,3-cyclohexadiene)(CO)₃, Ru(2,6-dimethyl-6-n-propyl-1,3-cyclohexadiene)(CO)₃, Ru(6-methyl-2,6-di-n-propyl-1,3-cyclohexadiene)(CO)₃, Ru(2-methyl-6,6-di-n-propyl-1,3-cyclohexadiene)(CO)₃,
Ru(5-methyl-1,5-di-n-propyl-1,3-cyclohexadiene)(CO)₃,
Ru(1-methyl-5,5-di-n-propyl-1,3-cyclohexadiene)(CO)₃,
Ru(6,6-dimethyl-3-n-propyl-1,3-cyclohexadiene)(CO)₃, Ru(5,5-dimethyl-2-n-propyl-1,3-cyclohexadiene)(CO)₃, Ru(3,6-dimethyl-6-n-propyl-1,3-cyclohexadiene)(CO)₃, Ru(6-methyl-3,6-di-n-propyl-1,3-cyclohexadiene)(CO)₃, Ru(3-methyl-6,6-di-n-propyl-1,3-cyclohexadiene)(CO)₃,
Ru(5-methyl-2,5-di-n-propyl-1,3-cyclohexadiene)(CO)₃, Ru(2-methyl-5,5-di-n-propyl-1,3-cyclohexadiene)(CO)₃,
Ru(1,3,5,5-tetramethyl-1,3-cyclohexadiene)(CO)₃,
Ru(1,3,5,5-tetraethyl-1,3-cyclohexadiene)(CO)₃,
Ru(2,3,5,5-tetramethyl-1,3-cyclohexadiene)(CO)₃,
Ru(3,4,6,6-tetramethyl-1,3-cyclohexadiene)(CO)₃,
Ru(2,3,5,5-tetraethyl-1,3-cyclohexadiene)(CO)₃,
Ru(3,4,6,6-tetraethyl-1,3-cyclohexadiene)(CO)₃,
Ru(1-ethyl-3,5,5-trimethyl-1,3-cyclohexadiene)(CO)₃,
Ru(2-ethyl-4,6,6-trimethyl-1,3-cyclohexadiene)(CO)₃,
Ru(3-ethyl-1,5,5-trimethyl-1,3-cyclohexadiene)(CO)₃,
Ru(4-ethyl-2,6,6-trimethyl-1,3-cyclohexadiene)(CO)₃,
Ru(5-ethyl-1,3,5-trimethyl-1,3-cyclohexadiene)(CO)₃,
Ru(6-ethyl-2,4,6-trimethyl-1,3-cyclohexadiene)(CO)₃,
Ru(1,3-diethyl-5,5-dimethyl-1,3-cyclohexadiene)(CO)₃,
Ru(2,4-diethyl-6,6-dimethyl-1,3-cyclohexadiene)(CO)₃,
Ru(1,5-diethyl-3,5-dimethyl-1,3-cyclohexadiene)(CO)₃,
Ru(2,6-diethyl-4,6-dimethyl-1,3-cyclohexadiene)(CO)₃,
Ru(3,5-diethyl-1,5-dimethyl-1,3-cyclohexadiene)(CO)₃,
Ru(4,6-diethyl-2,6-dimethyl-1,3-cyclohexadiene)(CO)₃,
Ru(1,2,3,5,5-pentamethyl-1,3-cyclohexadiene)(CO)₃,
Ru(2,3,4,6,6-pentamethyl-1,3-cyclohexadiene)(CO)₃,
Ru(1,2,3,5,5-pentaethyl-1,3-cyclohexadiene)(CO)₃,
Ru(2,3,4,6,6-pentaethyl-1,3-cyclohexadiene)(CO)₃,
Ru(1-ethyl-2,3,5,5-tetramethyl-1,3-cyclohexadiene)(CO)₃,
Ru(2-ethyl-3,4,6,6-tetramethyl-1,3-cyclohexadiene)(CO)₃,
Ru(2-ethyl-1,3,5,5-tetramethyl-1,3-cyclohexadiene)(CO)₃,
Ru(3-ethyl-2,4,6,6-tetramethyl-1,3-cyclohexadiene)(CO)₃,
Ru(3-ethyl-1,2,5,5-tetramethyl-1,3-cyclohexadiene)(CO)₃,
Ru(4-ethyl-2,3,6,6-tetramethyl-1,3-cyclohexadiene)(CO)₃,
Ru(5-ethyl-1,2,5,5-tetramethyl-1,3-cyclohexadiene)(CO)₃,
Ru(6-ethyl-2,3,4,6-tetramethyl-1,3-cyclohexadiene)(CO)₃,
Ru(spiro[2,5]octa-1,3-diene)(CO)₃,
Ru(spiro[3,5]nona-1,3-diene)(CO)₃,
Ru(spiro[4,5]deca-1,3-diene)(CO)₃,
Ru(spiro[5,5]-undeca-1,3-diene)(CO)₃
Ru(bicyclo[2,2,2]octadiene)(CO)₃, Ru(bicyclo[2,2,2]octatriene)(CO)₃, Ru(cyclohepta-1,3-diene)(CO)₃
Ru(gem-dimethylcyclopentadiene)(CO)₃, Ru(gem-diethylcyclopentadiene)(CO)₃,
Ru(1,3,5,5-tetramethyl-1,3-cyclohexadiene)(NCMe)₃, Ru(1,3,5,5-tetramethyl-1,3-cyclohexadiene)(CNMe)₃,
Ru(1,3,5,5-tetramethyl-1,3-cyclohexadiene)(NCEt)₃, Ru(1,3,5,5-tetramethyl-1,3-cyclohexadiene)(CNEt)₃,
Ru(1,3,5,5-tetramethyl-1,3-cyclohexadiene)(NCnBu)₃, Ru(1,3,5,5-tetramethyl-1,3-cyclohexadiene)(CNnBu)₃,
Ru(1,3,5,5-tetramethyl-1,3-cyclohexadiene)(NCsBu)₃, Ru(1,3,5,5-tetramethyl-1,3-cyclohexadiene)(CNsBu)₃,
Ru(1,3,5,5-tetramethyl-1,3-cyclohexadiene)(NCtBu)₃, Ru(1,3,5,5-tetramethyl-1,3-cyclohexadiene)(CNtBu)₃,
Ru(1,3,5,5-tetramethyl-1,3-cyclohexadiene)(P(Ph)₃)₃,
Ru(1,3,5,5-tetramethyl-1,3-cyclohexadiene)(P(Me)₃)₃,
Ru(1,3,5,5-tetramethyl-1,3-cyclohexadiene)(P(Et)₃)₃,
Ru(1,3,5,5-tetramethyl-1,3-cyclohexadiene)(P(OMe)₃)₃,
Ru(1,3,5,5-tetramethyl-1,3-cyclohexadiene)(P(OCH₂)₃CMe)₃.

### MODE(S) FOR CARRYING OUT THE INVENTION

All procedures were done under N₂ atmosphere with standard Schlenk or glove box techniques. 2-ethyl-4,6,6-trimethyl-1,3-cyclohexadiene and 2,6,6-trimethyl-1,3 cyclohexadiene were prepared by a reported method with minor modifications. Schmitt, J. Justus Liebigs Annalen der Chemie 1941, 547, 256. (NACD)Ru(CO)₃ were prepared by the method of WO2009057064 with minor modifications. (2-Et-4,6,6-Me₃-CHD)Ru(CO)₃ were prepared by a modified reported method from Ru₃(CO)₁₂ and 2-ethyl-4,6,6-tetramethyl-1,3-cyclohexadiene. (2,6,6-Trimethyl-1,3-cyclohexadiene)Ru(CO)₃ were prepared by a modified reported method from Ru₃(CO)₁₂ and 2,6,6-trimethyl-1,3-cyclohexadiene. (1,3-Cyclohexadiene)Ru(CO)₃ was prepared by a modified reported method from Ru₃(CO)₁₂ and 1,3-cyclohexadiene.

Thermal properties measurements were performed as follows. Thermogravimetric Analysis (TGA) was performed at 25 to 500° C. under atmospheric pressure (1000 mBar, N2 220 sccm) with an Aluminium open cup.

Vapor pressure was determined against Naphthalene as an external standard.

Melting point and decomposition point were determined by Differential Scanning Calorimetry (DSC) analysis in an Au-coated closed pan.

Ru containing film was deposited by flowing (NACD)Ru(CO)₃ with Ar carrier gas into the CVD reactor for 30 min. CVD reactor temperatures were varied from 240° C. to 385° C. on a SiO₂ wafer. Ru containing film was deposited by flowing (MeCHD)RuCO₃ with Ar carrier gas into the CVD reactor at 216° C. for 15 min. Both were deposited in the same condition except for the CVD reactor temperature.

TABLE 1
Thermal properties

| | M.p. | Temp._{VP = 1 torr} | Temp._{Decomp.} |
|---|---|---|---|
| Molecule | (° C.) | (° C.) | (° C.) |
| (1,3,5,5-Me₄—CHD)Ru(CO)₃ | <20 | 59.6 | 267 |
| (2-Et-4,6,6-Me₃—CHD)Ru(CO)₃ | <20 | 73.7 | 257 |
| (2,6,6-Me₃—CHD)Ru(CO)₃ | <20 | 67.8 | 260 |
| For Comparison | 35 | 55.5 | 142 |
| (CHD)Ru(CO)₃ | | | |
| For Comparison | <20 | 60.6 | 162 |
| (MeCHD)Ru(CO)₃ | | | |

As determined by TGA and DSC, the melting points of the three example species are below 20 degrees C. The temperatures at which 1 torr vapor pressure is measured are within 15 degrees C. of the comparison molecule (MeCHD)Ru(CO)₃. Thus the additional substituents did not significantly impact volatility. The melting point and 1 torr vapor pressure results are starkly contrasted against the decomposition temperatures, which are approximately 100 degrees C. higher than (MeCHD)Ru(CO)₃. This is consistent with the theorized effect of blocking the cyclodiene to aromatic dehydrogenation pathway for molecular decomposition.

Aromatizable CHD (1-MeCHD)RuCO₃ deposited Ru containing film at 216° C. in 15 min. In contrast, Nonaromatizable (1,3,5,5-Me₄-CHD)Ru(CO), has a higher pyrolysis temperature >240° C., with limited Ru deposition beginning before 264° C. Thus, the thermal CVD temperature range was shifted higher by more than 20 degrees C., a substantial improvement.

### INDUSTRIAL APPLICABILITY

The present invention is at least industrially applicable to the vapor phase deposition of Mo containing films, in particular Ru⁰ films.

While the invention has been described in conjunction with specific embodiments thereof, it is evident that many alternatives, modifications, and variations will be apparent to those skilled in the art in light of the foregoing description. Accordingly, it is intended to embrace all such alternatives, modifications, and variations as fall within the spirit and broad scope of the appended claims. The present invention may suitably comprise, consist or consist essentially of the elements disclosed and may be practiced in the absence of an element not disclosed. Furthermore, if there is language referring to order, such as first and second, it should be understood in an exemplary sense and not in a limiting sense. For example, it can be recognized by those skilled in the art that certain steps can be combined into a single step.

The singular forms “a”, “an” and “the” include plural referents, unless the context clearly dictates otherwise.

“Comprising” in a claim is an open transitional term which means the subsequently identified claim elements are a nonexclusive listing (i.e., anything else may be additionally included and remain within the scope of “comprising”). “Comprising” as used herein may be replaced by the more limited transitional terms “consisting essentially of” and “consisting of” unless otherwise indicated herein.

“Providing” in a claim is defined to mean furnishing, supplying, making available, or preparing something. The step may be performed by any actor in the absence of express language in the claim to the contrary.

Optional or optionally means that the subsequently described event or circumstances may or may not occur. The description includes instances where the eent or circumstance occurs and instances where it does not occur.

Ranges may be expressed herein as from about one particular value, and/or to about another particular value. When such a range is expressed, it is to be understood that another embodiment is from the one particular value and/or to the other particular value, along with all combinations within said range.

All references identified herein are each hereby incorporated by reference into this application in their entireties, as well as for the specific information for which each is cited.

1. A chemical suitable for use as a volatile precursor for vapor phase depositions of Ru containing materials, the chemical represented by the formula (NACD)-Ru-Lₓ, wherein x=1-3 and NACD is a non-aromatizable cyclic diene.

2. The chemical of claim 1, wherein the NACD has the formula I: 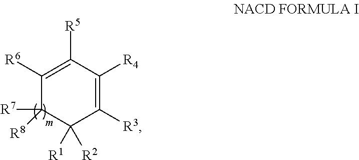
wherein R¹ and R² is a substituent covalently bound to a ring structure carbon via a carbon or silicon atom, and R¹ and R² may be the same or different,
wherein R³, R⁴, R⁵, R⁶, R⁷ and R⁸ each is independently selected from H or a covalently bound substituent,
wherein L is a neutral ligand, and
wherein m=0-3.

3. The chemical of claim 2, wherein R¹ and R² are selected from C₁-C₆ linear alkyl, C₁-C₆ branched alkyl, C₁-C₆ cyclic alkyl, C₁-C₆ alkenyl, C₁-C₆ alkynyl, C₁-C₆ alkylphenyl, C₁-C₆ alkenylphenyl, C₁-C₆ alkynylphenyl, aryl, C₁-C₆ fluoroalkyl or —SiR^{x}R^{y}R^{z}; and wherein for —SiR^{x}R^{y}R^{z}, R^{x}, R^{y}, and R^{z} each is independently selected from H, C₁-C₆ linear alkyl, C₁-C₆ branched alkyl, C₁-C₆ cyclic alkyl, C₁-C₆ alkenyl, C₁-C₆ alkylphenyl, C₁-C₆ alkenylphenyl, aryl, F, Cl, Br, and I.

4. The chemical of claim 2, wherein R³, R⁴, R⁵, R⁶, R⁷ and R⁸ each is independently selected from H, C₁-C₆ linear alkyl, C₁-C₆ branched alkyl, C₁-C₆ cyclic alkyl, C₁-C₆ alkenyl, C₁-C₆ alkylphenyl, C₁-C₆ alkenylphenyl, aryl, vinyl, or —SiR^{x}R^{y}R^{z}; wherein R^{x}, R^{y}, and R^{z} each is independently selected from H, C₁-C₆ linear alkyl, C₁-C₆ branched alkyl, C₁-C₆ cyclic alkyl, C₁-C₆ alkenyl, C₁-C₆ alkylphenyl, C₁-C₆ alkenylphenyl, aryl, F, Cl, Br, and I.

5. The chemical of claim 2, wherein m=1.

6. The chemical of claim 2, wherein R¹ and R² are C₁-C₄ linear alkyl or branched alkyl substituents, and R³-R⁸ are independently H, C₁-C₄ linear alkyl or branched alkyl substituents.

7. The chemical of claim 2, wherein R¹ and R² are both methyl groups.

8. The chemical of claim 2, wherein L is selected from CO, NCR⁹, CNR⁹, PR⁹₃; where R⁹ is independently selected from H, C₁-C₆ linear alkyl, C₁-C₆ branched alkyl, C₁-C₆ cyclic alkyl, C₁-C₆ alkenyl, C₁-C₆ alkylphenyl, C₁-C₆ alkenylphenyl, aryl, vinyl, or —SiR^{x}R^{y}R^{z}; wherein R^{x}, R^{y}, and R^{z} each is independently selected from H, C₁-C₆ linear alkyl, C₁-C₆ branched alkyl, C₁-C₆ cyclic alkyl, C₁-C₆ alkenyl, C₁-C₆ alkylphenyl, C₁-C₆ alkenylphenyl, aryl, F, Cl, Br, I; and combinations thereof, when x>1.

9. The chemical of claim 2, wherein x=3 and L is CO.

10. The chemical of claim 2, selected from:
Ru(6,6-dimethyl-1,3-cyclohexadiene)(CO)₃, Ru(6,6-diethyl-1,3-cyclohexadiene)(CO)₃, Ru(6,6-di(n-propyl)-1,3-cyclohexadiene)(CO)₃, Ru(6,6-di(isopropyl)-1,3-cyclohexadiene)(CO)₃,
Ru(6-ethyl-6-methyl-1,3-cyclohexadiene)(CO)₃, Ru(6-methyl-6-(n-propyl)-1,3-cyclohexadiene)(CO)₃, Ru(6-methyl-6-(iso-propyl)-1,3-cyclohexadiene)(CO)₃,
Ru(6-(n-butyl)-6-methyl-1,3-cyclohexadiene)(CO)₃, Ru(6-(sec-butyl)-6-methyl-1,3-cyclohexadiene)(CO)₃,
Ru(2,6,6-trimethyl-1,3-cyclohexadiene)(CO)₃, Ru(1,5,5-trimethyl-1,3-cyclohexadiene)(CO)₃, Ru(3,6,6-trimethyl-1,3-cyclohexadiene)(CO)₃, Ru(2,6,6-triethyl-1,3-cyclohexadiene)(CO)₃, Ru(1,5,5-triethyl-1,3-cyclohexadiene)(CO)₃, Ru(3,6,6-triethyl-1,3-cyclohexadiene)(CO)₃,
Ru(2,6,6-tri-iso-propyl-1,3-cyclohexadiene)(CO)₃, Ru(1,5,5-tri-iso-propyl-1,3-cyclohexadiene)(CO)₃, Ru(2,6,6-n-iso-propyl-1,3-cyclohexadiene)(CO)₃, Ru(1,5,5-n-iso-propyl-1,3-cyclohexadiene)(CO)₃,
Ru(2-ethyl-6,6-dimethyl-1,3-cyclohexadiene)(CO)₃, Ru(1-ethyl-5,5-dimethyl-1,3-cyclohexadiene)(CO)₃, Ru(6-ethyl-2,6-dimethyl-1,3-cyclohexadiene)(CO)₃,
Ru(2,6-diethyl-6-methyl-1,3-cyclohexadiene)(CO)₃, Ru(6,6-diethyl-2-methyl-1,3-cyclohexadiene)(CO)₃,
Ru(1,5-diethyl-5-methyl-1,3-cyclohexadiene)(CO)₃, Ru(5,5-diethyl-1-methyl-1,3-cyclohexadiene)(CO)₃,
Ru(3-ethyl-6,6-dimethyl-1,3-cyclohexadiene)(CO)₃, Ru(2-ethyl-5,5-dimethyl-1,3-cyclohexadiene)(CO)₃, Ru(6-ethyl-3,6-dimethyl-1,3-cyclohexadiene)(CO)₃, Ru(3,6-diethyl-6-methyl-1,3-cyclohexadiene)(CO)₃, Ru(6,6-diethyl-3-methyl-1,3-cyclohexadiene)(CO)₃,
Ru(2,5-diethyl-5-methyl-1,3-cyclohexadiene)(CO)₃, Ru(5,5-diethyl-2-methyl-1,3-cyclohexadiene)(CO)₃,
Ru(6,6-dimethyl-2-iso-propyl-1,3-cyclohexadiene)(CO)₃, Ru(5,5-dimethyl-1-iso-propyl-1,3-cyclohexadiene)(CO)₃, Ru(2,6-dimethyl-6-iso-propyl-1,3-cyclohexadiene)(CO)₃, Ru(6-methyl-2,6-di-iso-propyl-1,3-cyclohexadiene)(CO)₃, Ru(2-methyl-6,6-di-iso-propyl-1,3-cyclohexadiene)(CO)₃,
Ru(5-methyl-1,5-di-iso-propyl-1,3-cyclohexadiene)(CO)₃, Ru(1-methyl-5,5-di-iso-propyl-1,3-cyclohexadiene)(CO)₃,
Ru(6,6-dimethyl-3-iso-propyl-1,3-cyclohexadiene)(CO)₃, Ru(5,5-dimethyl-2-iso-propyl-1,3-cyclohexadiene)(CO)₃, Ru(3,6-dimethyl-6-iso-propyl-1,3-cyclohexadiene)(CO)₃, Ru(6-methyl-3,6-di-iso-propyl-1,3-cyclohexadiene)(CO)₃, Ru(3-methyl-6,6-di-iso-propyl-1,3-cyclohexadiene)(CO)₃,
Ru(5-methyl-2,5-di-iso-propyl-1,3-cyclohexadiene)(CO)₃, Ru(2-methyl-5,5-di-iso-propyl-1,3-cyclohexadiene)(CO)₃,
Ru(6,6-dimethyl-2-n-propyl-1,3-cyclohexadiene)(CO)₃, Ru(5,5-dimethyl-1-n-propyl-1,3-cyclohexadiene)(CO)₃, Ru(2,6-dimethyl-6-n-propyl-1,3-cyclohexadiene)(CO)₃, Ru(6-methyl-2,6-di-n-propyl-1,3-cyclohexadiene)(CO)₃, Ru(2-methyl-6,6-di-n-propyl-1,3-cyclohexadiene)(CO)₃,
Ru(5-methyl-1,5-di-n-propyl-1,3-cyclohexadiene)(CO)₃,
Ru(1-methyl-5,5-di-n-propyl-1,3-cyclohexadiene)(CO)₃,
Ru(6,6-dimethyl-3-n-propyl-1,3-cyclohexadiene)(CO)₃, Ru(5,5-dimethyl-2-n-propyl-1,3-cyclohexadiene)(CO)₃, Ru(3,6-dimethyl-6-n-propyl-1,3-cyclohexadiene)(CO)₃, Ru(6-methyl-3,6-di-n-propyl-1,3-cyclohexadiene)(CO)₃, Ru(3-methyl-6,6-di-n-propyl-1,3-cyclohexadiene)(CO)₃,
Ru(5-methyl-2,5-di-n-propyl-1,3-cyclohexadiene)(CO)₃, Ru(2-methyl-5,5-di-n-propyl-1,3-cyclohexadiene)(CO)₃,
Ru(1,3,5,5-tetramethyl-1,3-cyclohexadiene)(CO)₃,
Ru(1,3,5,5-tetraethyl-1,3-cyclohexadiene)(CO)₃,
Ru(2,3,5,5-tetramethyl-1,3-cyclohexadiene)(CO)₃,
Ru(3,4,6,6-tetramethyl-1,3-cyclohexadiene)(CO)₃,
Ru(2,3,5,5-tetraethyl-1,3-cyclohexadiene)(CO)₃,
Ru(3,4,6,6-tetraethyl-1,3-cyclohexadiene)(CO)₃,
Ru(1-ethyl-3,5,5-trimethyl-1,3-cyclohexadiene)(CO)₃,
Ru(2-ethyl-4,6,6-trimethyl-1,3-cyclohexadiene)(CO)₃,
Ru(3-ethyl-1,5,5-trimethyl-1,3-cyclohexadiene)(CO)₃,
Ru(4-ethyl-2,6,6-trimethyl-1,3-cyclohexadiene)(CO)₃,
Ru(5-ethyl-1,3,5-trimethyl-1,3-cyclohexadiene)(CO)₃,
Ru(6-ethyl-2,4,6-trimethyl-1,3-cyclohexadiene)(CO)₃,
Ru(1,3-diethyl-5,5-dimethyl-1,3-cyclohexadiene)(CO)₃,
Ru(2,4-diethyl-6,6-dimethyl-1,3-cyclohexadiene)(CO)₃,
Ru(1,5-diethyl-3,5-dimethyl-1,3-cyclohexadiene)(CO)₃,
Ru(2,6-diethyl-4,6-dimethyl-1,3-cyclohexadiene)(CO)₃,
Ru(3,5-diethyl-1,5-dimethyl-1,3-cyclohexadiene)(CO)₃,
Ru(4,6-diethyl-2,6-dimethyl-1,3-cyclohexadiene)(CO)₃,
Ru(1,2,3,5,5-pentamethyl-1,3-cyclohexadiene)(CO)₃,
Ru(2,3,4,6,6-pentamethyl-1,3-cyclohexadiene)(CO)₃,
Ru(1,2,3,5,5-pentaethyl-1,3-cyclohexadiene)(CO)₃,
Ru(2,3,4,6,6-pentaethyl-1,3-cyclohexadiene)(CO)₃,
Ru(1-ethyl-2,3,5,5-tetramethyl-1,3-cyclohexadiene)(CO)₃,
Ru(2-ethyl-3,4,6,6-tetramethyl-1,3-cyclohexadiene)(CO)₃,
Ru(2-ethyl-1,3,5,5-tetramethyl-1,3-cyclohexadiene)(CO)₃,
Ru(3-ethyl-2,4,6,6-tetramethyl-1,3-cyclohexadiene)(CO)₃,
Ru(3-ethyl-1,2,5,5-tetramethyl-1,3-cyclohexadiene)(CO)₃,
Ru(4-ethyl-2,3,6,6-tetramethyl-1,3-cyclohexadiene)(CO)₃,
Ru(5-ethyl-1,2,5,5-tetramethyl-1,3-cyclohexadiene)(CO)₃,
Ru(6-ethyl-2,3,4,6-tetramethyl-1,3-cyclohexadiene)(CO)₃,
Ru(gem-dimethylcyclopentadiene)(CO)₃, Ru(gem-diethylcyclopentadiene)(CO)₃,
Ru(1,3,5,5-tetramethyl-1,3-cyclohexadiene)(NCMe)₃, Ru(1,3,5,5-tetramethyl-1,3-cyclohexadiene)(CNMe)₃,
Ru(1,3,5,5-tetramethyl-1,3-cyclohexadiene)(NCEt)₃, Ru(1,3,5,5-tetramethyl-1,3-cyclohexadiene)(CNEt)₃,
Ru(1,3,5,5-tetramethyl-1,3-cyclohexadiene)(NCnBu)₃, Ru(1,3,5,5-tetramethyl-1,3-cyclohexadiene)(CNnBu)₃,
Ru(1,3,5,5-tetramethyl-1,3-cyclohexadiene)(NCsBu)₃, Ru(1,3,5,5-tetramethyl-1,3-cyclohexadiene)(CNsBu)₃,
Ru(1,3,5,5-tetramethyl-1,3-cyclohexadiene)(NCtBu)₃, Ru(1,3,5,5-tetramethyl-1,3-cyclohexadiene)(CNtBu)₃,
Ru(1,3,5,5-tetramethyl-1,3-cyclohexadiene)(P(Ph)₃)₃,
Ru(1,3,5,5-tetramethyl-1,3-cyclohexadiene)(P(Me)₃)₃,
Ru(1,3,5,5-tetramethyl-1,3-cyclohexadiene)(P(Et)₃)₃,
Ru(1,3,5,5-tetramethyl-1,3-cyclohexadiene)(P(OMe)₃)₃,
Ru(1,3,5,5-tetramethyl-1,3-cyclohexadiene)(P(OCH₂)₃CMe)₃, and combinations thereof.

11. A composition comprising the chemical of claim 1.

12. The composition of claim 11, wherein the composition is a vapor phase composition.

13. The composition of claim 12, wherein the vapor phase composition comprises a vapor of the chemical mixed with a carrier gas.

14. The composition of claim 13, wherein the carrier gas comprises Argon, Helium and/or Nitrogen gas.

15. The chemical of claim 1, wherein the NACD has the formula II: 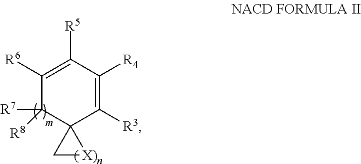
wherein R¹ and R² is a substituent covalently bound to a ring structure carbon via a carbon or silicon atom, and R¹ and R² may be the same or different,
wherein R³, R⁴, R⁵, R⁶, R⁷ and R⁸ each is independently selected from H or a covalently bound substituent,
wherein L is a neutral ligand,
wherein X is selected from —CR^{x}R^{y}—, —NR^{x}—, —O—, —S—, —SiR^{x}R^{y}—; wherein R^{x}, R^{y}, and R^{z} each is independently selected from H, C₁-C₆ linear alkyl, C₁-C₆ branched alkyl, C₁-C₆ cyclic alkyl, C₁-C₆ alkenyl, C₁-C₆ alkylphenyl, C₁-C₆ alkenylphenyl, aryl, F, Cl, Br, and I, and
wherein m=0-3 and n=1-7.

16. A method of vapor phase depositing a Ru containing material on a surface, the method comprising
a. providing a substrate having a surface, and
b. exposing the substrate to a vapor phase of the chemical of claim 1, under conditions suitable to form a deposited material, comprising the Ru, on the surface.

17. The method of claim 16 further comprising a step of exposing the substrate to a co-reactant selected from the group consisting of H₂, NH₃, SiH₄, Si₂H₆, Si₃H₈, hydrogen containing fluids, hydrogen radicals, and mixtures thereof.

18. The method of claim 16 further comprising a step of exposing the substrate to a co-reactant selected from the group consisting of O₂, O₃, H₂O, H₂O₂, oxygen containing radicals, and mixtures thereof.

19. The method of claim 16, wherein the deposited material is a contiguous and conformal film or layer on the surface of the substrate.

20. The method of claim 17, wherein the deposited material comprises 50% to 99.99% Ru by atomic percent.
